(19) United States
(12) Patent Application Publication
(10) Pub. No.: US 2024/0381696 A1
(43) Pub. Date: Nov. 14, 2024

(54) DISPLAY DEVICE AND ELECTRONIC DEVICE

(71) Applicant: SONY SEMICONDUCTOR SOLUTIONS CORPORATION, KANAGAWA (JP)

(72) Inventors: TAKAYUKI SAKAGUCHI, KANAGAWA (JP); KEI KIMURA, KANAGAWA (JP); KAZUKI YOKOYAMA, KANAGAWA (JP)

(21) Appl. No.: 18/554,660

(22) PCT Filed: Mar. 20, 2022
(86) PCT No.: PCT/JP2022/015941

§ 371 Date: Oct. 10, 2023

(30) Foreign Application Priority Data
Apr. 26, 2021 (JP) 2021-074288

(51) Int. Cl. H10K 59/121; G09G 3/3233

(52) U.S. Cl. CPC H10K 59/1216; G09G 3/3233; G09G 2300/0426; G09G 2300/0819; G09G 2300/0852; G09G 2310/08; G09G 2320/02

(57) ABSTRACT

To further reduce manufacturing steps and improve display characteristics. A display device includes: a light emitting element; a first capacitor including a first electrode and a second electrode; a second capacitor including a third electrode and a fourth electrode; and a drive transistor that supplies, to the light emitting element, a current corresponding to a voltage accumulated in the first capacitor and a voltage accumulated in the second capacitor, in which the second electrode is electrically connected to the third electrode, and the second electrode and the third electrode are disposed in different layers.

### TECHNICAL FIELD

Embodiments according to the present disclosure relate to a display device and an electronic device.

### BACKGROUND ART

In recent years, in a field of a display device that performs image display, a planar display device in which pixels (pixel circuits) including light emitting elements are arranged in a matrix form has been rapidly spread. For the planar display device, as the light emitting element of a pixel, an organic EL display device using a so-called current drive type electro-optical element in which light emission luminance changes according to a current value flowing through the device, for example, an organic electro luminescence (EL) element utilizing a phenomenon in which light is emitted when an electric field is applied to an organic thin film has been developed and commercialized.

In the pixel circuit, for example, a plurality of capacitors used for correction of variations in characteristics of transistors, assistance of capacitance of organic EL elements, and the like may be provided (See Patent Document 1).

### CITATION LIST

### Patent Document

Patent Document 1: Japanese Patent Application Laid-Open No. 2009-47765

### SUMMARY OF THE INVENTION

### Problems to be Solved by the Invention

However, when the plurality of capacitors is arranged in a plurality of layers, the number of steps increases and the cost increases. Furthermore, it may be difficult to increase the electrostatic capacitance of the capacitor due to layout restrictions and the like. In this case, for example, correction of variations in characteristics of the transistor and the like cannot be appropriately performed, and there is a possibility that it becomes difficult to improve display characteristics such as image quality.

Therefore, the present disclosure provides a display device and an electronic device that can further reduce the number of manufacturing steps and improve display characteristics.

### Solutions to Problems

In order to solve the problems described above, according to the present disclosure, provided is a display device including: a light emitting element; a first capacitor including a first electrode and a second electrode; a second capacitor including a third electrode and a fourth electrode; and a drive transistor that supplies, to the light emitting element, a current corresponding to a voltage accumulated in the first capacitor and a voltage accumulated in the second capacitor, in which the second electrode is electrically connected to the third electrode, and the second electrode and the third electrode are disposed in different layers.

The display device may further include a metal layer that is disposed in a layer different from the first capacitor and the second capacitor so as to overlap with the first electrode and the second electrode when viewed from a lamination direction, and is electrically connected to the second electrode and the third electrode.

The metal layer may be disposed so as to cover the first electrode and the second electrode when viewed from the lamination direction.

The metal layer may be disposed so as to overlap with the first electrode disposed so as to cover the second electrode when viewed from the lamination direction.

The first electrode may be electrically connected to a gate of the drive transistor, and the second electrode, the third electrode, and the metal layer may be electrically connected to a source of the drive transistor.

The first electrode may be electrically connected to a voltage supply wiring that supplies a predetermined voltage, and the second electrode, the third electrode, and the metal layer may be electrically connected to a gate of the drive transistor.

The metal layer may be disposed so as to overlap with a voltage supply wiring that supplies a predetermined voltage when viewed from the lamination direction.

The fourth electrode may be electrically connected to the voltage supply wiring.

The metal layer may be disposed so as to overlap with the first electrode electrically connected to a gate of the drive transistor when viewed from the lamination direction.

The first electrode electrically connected to the gate may be disposed so as to overlap with a signal line when viewed from the lamination direction, and the metal layer may be disposed in a layer between a layer in which the first electrode is disposed and a layer in which the signal line is disposed.

The display device may further include a plurality of columnar electrode portions provided so as to extend in the lamination direction and electrically connecting each of the second electrode and the third electrode to the metal layer, in which the metal layer may be disposed so as to electrically connect the second electrode and the third electrode via a plurality of the columnar electrode portions.

The first capacitor may accumulate a first voltage related to an operation of the drive transistor, and the second capacitor may accumulate a second voltage different from the first voltage.

A plurality of the capacitors may be at least one or more capacitors of a metal-insulator-metal (MIM) capacitor, a metal-oxide-metal (MOM) capacitor, and a metal-oxide-semiconductor (MOS) capacitor.

According to the present disclosure, provided is an electronic device including: a light emitting element; a first capacitor including a first electrode and a second electrode; a second capacitor including a third electrode and a fourth electrode; and a drive transistor that supplies, to the light emitting element, a current corresponding to a voltage accumulated in the first capacitor and a voltage accumulated in the second capacitor, in which the second electrode is electrically connected to the third electrode, and the second electrode and the third electrode are disposed in different layers.

### BRIEF DESCRIPTION OF DRAWINGS

FIG. 1 is a block diagram illustrating a schematic configuration of a display device according to a first embodiment of the present disclosure.

FIG. 2 is a circuit diagram illustrating an example of an internal configuration of a pixel circuit according to the first embodiment.

FIG. 3 is a timing chart illustrating an example of an operation of the pixel circuit 11 according to the first embodiment.

FIG. 4 is a cross-sectional view illustrating an example of a configuration of a first capacitor and a second capacitor according to the first embodiment.

FIG. 5 is a plan view illustrating an example of a configuration of the first capacitor and the second capacitor according to the first embodiment.

FIG. 6 is a cross-sectional view illustrating an example of a configuration of a first capacitor and a second capacitor according to a first comparative example.

FIG. 7 is a cross-sectional view illustrating an example of a configuration of a first capacitor and a second capacitor according to a second comparative example.

FIG. 8 is a circuit diagram illustrating an example of an internal configuration of a pixel circuit according to a modification example of the first embodiment.

FIG. 9 is a circuit diagram illustrating an example of an internal configuration of a pixel circuit according to a second embodiment.

FIG. 10 is a circuit diagram illustrating an example of an internal configuration of a pixel circuit according to a third embodiment.

FIG. 11 is a cross-sectional view illustrating an example of a capacitor and a configuration of the capacitor according to the third embodiment.

FIG. 12 is a plan view illustrating an example of the capacitor and a configuration of the capacitor according to the third embodiment.

FIG. 13 is a circuit diagram illustrating an example of an internal configuration of a pixel circuit according to a fourth embodiment.

FIG. 14 is a circuit diagram illustrating an example of an internal configuration of a pixel circuit according to a fifth embodiment.

FIG. 15 is a circuit diagram illustrating an example of an internal configuration of a pixel circuit according to a sixth embodiment.

FIG. 16A is a diagram illustrating an internal state of a vehicle from a rear side to a front side of the vehicle.

FIG. 16B is a diagram illustrating an internal state of the vehicle from an oblique rear side to an oblique front side of the vehicle.

FIG. 17A is a front view of a digital camera as a second application example of an electronic device.

FIG. 17B is a rear view of the digital camera.

FIG. 18A is an external view of an HMD that is a third application example of the electronic device.

FIG. 18B is an external view of a smart glass.

FIG. 19 is an external view of a TV that is a fourth application example of the electronic device.

FIG. 20 is an external view of a smartphone that is a fifth application example of the electronic device.

### MODE FOR CARRYING OUT THE INVENTION

Hereinafter, embodiments of a display device and an electronic device will be described with reference to the drawings. Although main configuration parts of the display device and the electronic device will be mainly described below, the display device and the electronic device may have configuration parts and functions that are not illustrated or described. The following description does not exclude configuration parts and functions that are not illustrated or described.

### First Embodiment

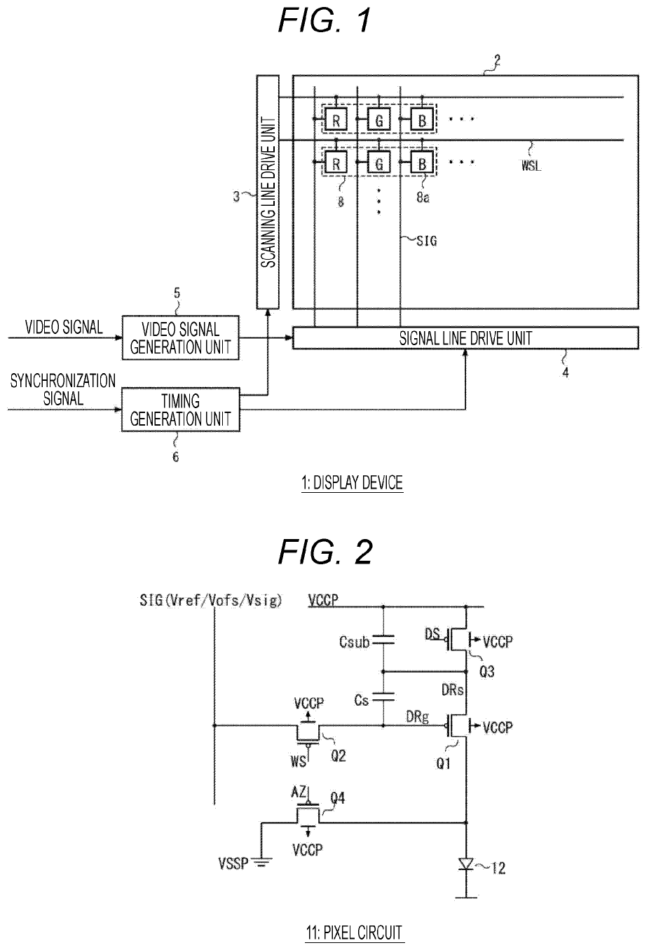

FIG. 1 is a block diagram illustrating a schematic configuration of a display device 1 according to a first embodiment of the present disclosure. The display device 1 of FIG. 1 can be exemplified by an organic EL display device, a liquid crystal display device, a plasma display device, and the like. Among these display devices, the organic EL display device uses an organic EL element (hereinafter, organic light emitting device (OLED)) that uses electroluminescence of an organic material and uses a phenomenon of emitting light when an electric field is applied to an organic thin film as a light emitting element (electro-optical element) of a pixel.

The display device 1 of FIG. 1 includes a pixel array unit 2, a scanning line drive unit 3, a signal line drive unit 4, a video signal processing unit 5, and a timing generation unit 6.

The pixel array unit 2 includes a plurality of pixels 8 arranged in each of a row direction and a column direction. Each of the pixels 8 includes a plurality of subpixels 8a. The plurality of subpixels 8a includes, for example, three subpixels 8a of red, blue, and green. The plurality of subpixels 8a may include subpixels 8a of colors other than red, blue, and green (for example, white). In the present specification, the subpixel 8a may be collectively referred to as the pixel 8.

Each of the subpixel 8a in the pixel 8 includes a display element and a pixel circuit as described later. The display element is, for example, an OLED. Note that the display element may be a liquid crystal element or a self-light-emitting element other than the OLED.

The pixel array unit 2 includes a plurality of scanning lines WSL arranged for each pixel group in the row direction and a plurality of signal lines SIG arranged for each pixel group in the column direction. The pixel 8 is provided near each of intersections of the scanning lines WSL and the signal lines SIG. In the present specification, the row direction may be referred to as a horizontal line direction, and the column direction may be referred to as a vertical line direction.

The scanning line drive unit 3 sequentially drives the plurality of scanning lines WSL. The signal line drive unit 4 drives the plurality of signal lines SIG in the horizontal line direction at the same timing in synchronization with the timing at which each of the scanning lines WSL drives each horizontal line. Driving the signal lines SIG means supplying a gradation signal corresponding to each of the signal lines SIG.

The video signal processing unit 5 performs predetermined signal processing on a video signal supplied from the outside (for example, a processor) to generate the gradation signal. The predetermined signal processing is, for example, processing such as gamma correction and overdrive correction.

The timing generation unit 6 supplies a timing control signal to the scanning line drive unit 3 and the signal line drive unit 4 on the basis of a synchronization signal supplied from the outside, and operates the scanning line drive unit 3 and the signal line drive unit 4 in synchronization.

The number of pixels in the pixel array unit 2 in FIG. 1 is not particularly limited. In the high-definition display device 1 having a large number of pixels, the scanning line drive unit 3 may be arranged on both end sides in the horizontal line direction. Furthermore, in order to drive the plurality of signal lines SIG in the horizontal line direction separately, a plurality of the signal line drive units 4 may be provided.

FIG. 2 is a circuit diagram illustrating an example of an internal configuration of a pixel circuit 11 according to the first embodiment. FIG. 2 illustrates an example of the pixel circuit 11 that controls light emission of an OLED 12 in a case where the OLED 12 is used as a display element. The pixel circuit 11 of FIG. 2 includes four transistors Q1 to 04 called 4Tr2C and two capacitors (a first capacitor Cs and a second capacitor Csub). In the present specification, the four transistors Q1 to 04 in the pixel circuit 11 are referred to as a drive transistor Q1, a sampling transistor Q2, a drive scan transistor Q3, and an auto-zero transistor Q4. The drive transistor Q1 may be abbreviated as a Drv transistor Q1, the sampling transistor Q2 may be referred to as a WS transistor Q2, the drive scan transistor Q3 may be referred to as a DS transistor Q3, and the auto-zero transistor Q4 may be referred to as an AZ transistor Q4.

In the pixel circuit 11 of FIG. 2, an example in which the Drv transistor Q1, the WS transistor Q2, the DS transistor Q3, and the AZ transistor Q4 are configured by P-type metal-oxide-semiconductor (MOS) transistors is illustrated, but as will be described later, the Drv transistor Q1, the WS transistor Q2, the DS transistor Q3, and the AZ transistor Q4 may be configured by N-type MOS transistors.

The DS transistor Q3 and the Drv transistor Q1 are cascode-connected between a power supply voltage node VCCP and an anode of the OLED 12. The WS transistor Q2 is connected between the signal line SIG and a gate of the Drv transistor Q1. In FIG. 2, a signal input to a gate of the WS transistor Q2 is referred to as a WS signal, and a signal input to a gate of the DS transistor Q3 is referred to as a DS signal. A gradation signal and an offset signal are supplied to the signal line SIG at different timings.

The AZ transistor Q4 is connected between the anode of the OLED 12 and a ground voltage node VSSP. An AZ signal is supplied to a gate of the AZ transistor Q4. In a case where the AZ transistor Q4 is a P-type MOS transistor, when the AZ signal is low, a source-drain current of the Drv transistor Q1 passes through the AZ transistor Q4 and flows to the ground voltage node VSSP. Therefore, while the AZ transistor Q4 is on, an increase in an anode voltage of the OLED 12 is suppressed, and the current does not flow through the OLED 12.

The first capacitor Cs is connected between the gate and the source of the Drv transistor Q1. Furthermore, the second capacitor Csub is connected between the source and the drain of the DS transistor Q3. That is, the first capacitor Cs and the second capacitor Csub are connected in series between the power supply voltage node VCCP and the gate of the Drv transistor Q1. The first capacitor Cs may be referred to as a pixel capacitance, and the second capacitor Csub may be referred to as an auxiliary capacitance.

The first capacitor Cs and the second capacitor Csub are, for example, metal-insulator-metal (MIM) capacitors. In this case, for example, at least one electrode of the capacitor is disposed in a wiring layer.

A cathode of the OLED 12 is fixed to a predetermined voltage (for example, a ground voltage).

Next, an operation of the pixel circuit 11 illustrated in FIG. 2 will be described.

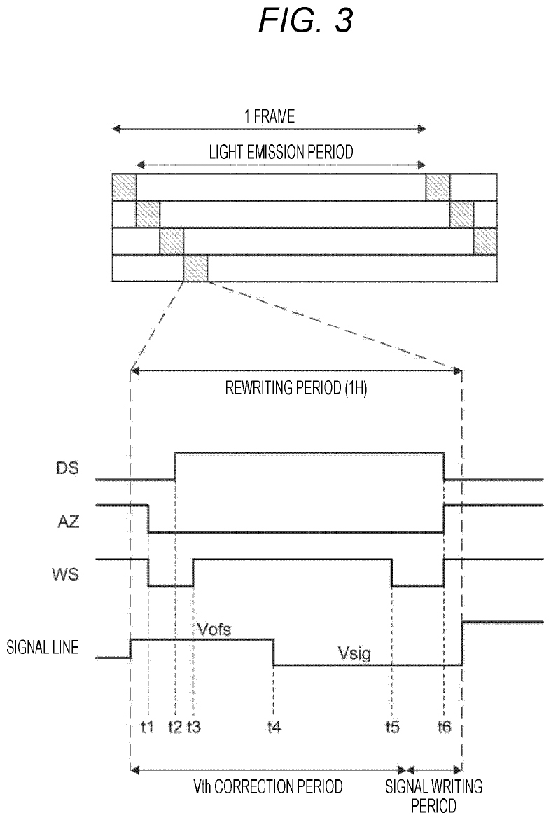

FIG. 3 is a timing chart illustrating an example of the operation of the pixel circuit 11 according to the first embodiment.

The signal line drive unit 4 generates a drive voltage of all the signal lines SIG each time the scanning line drive unit 3 drives one scanning line WSL. The plurality of scanning lines WSL is provided in one frame, and the plurality of pixels connected to one scanning line WSL is referred to as one horizontal line (1H). FIG. 3 illustrates a timing chart of representative signals in a pixel circuit in a case where all pixels in one frame are sequentially driven for each horizontal line. A signal DS is a gate signal of the DS transistor Q3. A signal AZ is a gate signal of the AZ transistor Q4. A signal WS is a gate signal of the WS transistor Q2.

Hereinafter, the operation of the pixel circuit of FIG. 2 will be described on the basis of the timing chart of FIG. 3. First, since the signal AZ transitions from high to low at time t1, the AZ transistor Q4 is turned on, and the light emission of the OLED 12 is stopped. Furthermore, the WS transistor Q2 is turned on, and an offset voltage Vofs on the signal line SIG is supplied to one end of the first capacitor Cs. At this time, the DS transistor Q3 is turned on, and the power supply voltage VCCP is supplied to the other end of the first capacitor Cs. Therefore, a voltage of (VCCP-Vofs) is applied to both ends of the first capacitor Cs.

Thereafter, at time t2, the DS transistor Q3 is turned off. As a result, a part of charges accumulated in the first capacitor Cs moves to the second capacitor Csub, and the charges are distributed. Specifically, charges corresponding to a threshold voltage of the Drv transistor Q1 are accumulated in the first capacitor Cs.

Thereafter, at time t3, the WS transistor Q2 is turned off. Thereafter, at time t4, a signal line voltage Vsig is supplied onto the signal line SIG. Thereafter, at time t5, the WS transistor Q2 is turned on, and the signal line voltage Vsig is supplied to the gate of the Drv transistor Q1. Since the correction corresponding to the threshold voltage of the Drv transistor Q1 is performed by the first capacitor Cs, a voltage subjected to offset correction and threshold correction with respect to the signal line voltage Vsig is applied between the gate and the source of the Drv transistor Q1.

As described above, the first capacitor Cs and the second capacitor Csub are used for the offset correction and the threshold correction, for example. By performing the threshold correction, it is possible to correct the variation in the threshold voltage of the Drv transistor Q1, and it is possible to suppress deterioration of the image quality of the display image. For example, the surface roughness can be corrected by the threshold correction. Furthermore, the larger the capacitances of the first capacitor Cs and the second capacitor Csub, the more appropriately the correction can be performed.

Next, a configuration of the first capacitor Cs and the second capacitor Csub, and a peripheral configuration thereof will be described.

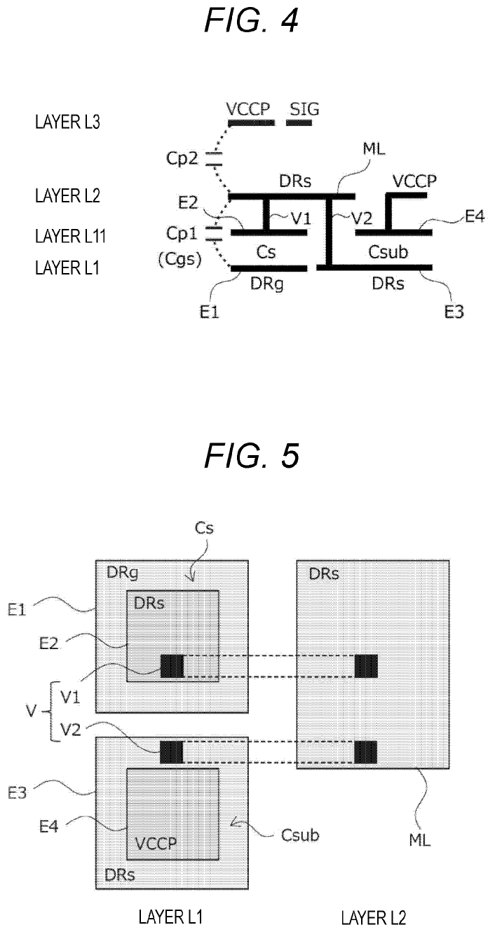

FIG. 4 is a cross-sectional view illustrating an example of a configuration of the first capacitor Cs and the second capacitor Csub according to the first embodiment. FIG. 5 is a plan view illustrating an example of a configuration of the first capacitor Cs and the second capacitor Csub according to the first embodiment.

FIGS. 4 and 5 illustrate a part of the laminated structure of the pixel circuit 11 around the first capacitor Cs and the second capacitor Csub. Layers L1, L2, and L3 are wiring layers, and are layers in which one electrode portion of wiring and a capacitor is disposed, for example. Among the layers L1, L2, and L3, the layer L1 is the lowermost layer, and the layer L3 is the uppermost layer. Furthermore, the layer L11 is a layer between the layer L1 and the layer L2, and is, for example, a layer in which the other electrode portion of the capacitor is disposed. However, the present disclosure is not limited thereto, and the layers L1, L2, and L3 may be layers between wiring layers, and the layer L11 may be a wiring layer. Furthermore, the wirings arranged in different layers and the wirings and the electrode portions arranged in different layers are partially electrically connected by, for example, vias V (columnar electrodes).

The pixel circuit 11 illustrated in FIGS. 4 and 5 includes the first capacitor Cs, the second capacitor Csub, a metal layer ML, and a via V.

The first capacitor Cs has two electrode portions and holds a first voltage related to the operation of the OLED 12. More specifically, the first capacitor Cs includes a first electrode portion E1 and a second electrode portion E2. The first electrode portion E1 and the second electrode portion E2 are disposed so as to sandwich an insulating layer therebetween.

The second capacitor Csub is disposed in the same layer as the first capacitor Cs. The second capacitor Csub includes two electrode portions and holds a second voltage related to the operation of the OLED 12. The second voltage is different from the first voltage, for example. That is, the first capacitor Cs and the second capacitor Csub have different functions. However, the second voltage may be the same as the first voltage. Each of the two electrode portions of the second capacitor Csub is disposed in the same layer as each of the two electrode portions of the first capacitor Cs. More specifically, the second capacitor Csub includes a third electrode portion E3 and a fourth electrode portion E4. The third electrode portion E3 and the fourth electrode portion E4 are disposed so as to sandwich an insulating layer therebetween.

The first electrode portion E1 (first electrode) is disposed, for example, in the layer L1. The second electrode portion E2 (second electrode) is disposed in the layer L11, for example. In the example illustrated in FIG. 5, the lower first electrode portion E1 is formed larger than the upper second electrode portion E2 by the manufacturing process. That is, the second electrode portion E2 is included in the first electrode portion E1 as viewed from a lamination direction. The lamination direction is a vertical direction along the paper surface of FIG. 4, and is a direction perpendicular to the paper surface of FIG. 5.

The third electrode portion E3 (third electrode) is disposed in the layer L1 that is the same layer as the first electrode portion E1. The fourth electrode portion E4 (fourth electrode) is disposed in the layer L11 that is the same layer as the second electrode portion E2. In the example illustrated in FIG. 5, the lower third electrode portion E3 is formed larger than the upper fourth electrode portion E4 by the manufacturing process. That is, the fourth electrode portion E4 is included in the third electrode portion E3 as viewed from the lamination direction.

Furthermore, one electrode portion of the first capacitor Cs and one electrode portion of the second capacitor Csub are common electrode portions. The common electrode portions include one electrode portion of a certain capacitor, and are electrode portions electrically connected between the plurality of capacitors. Furthermore, the common electrode portions are disposed in the two layers, respectively, in which the two electrode portions of the capacitor are disposed. In the example illustrated in FIGS. 4 and 5, the second electrode portion E2 disposed in the layer L11 and the third electrode portion E3 disposed in the layer L1 are the common electrode portions.

Furthermore, as illustrated in FIG. 2, the source DRs of the Drv transistor Q1 is connected to a node between the first capacitor Cs and the second capacitor Csub. Therefore, the source DRs is electrically connected to one electrode portion (one end) of each of the capacitors electrically connected to each other between the first capacitor Cs and the second capacitor Csub. In the example illustrated in FIGS. 4 and 5, the source DRs is electrically connected to the common electrode portions, that is, the second electrode portion E2 and the third electrode portion E3.

Furthermore, as illustrated in FIG. 2, the gate DRg of the Drv transistor Q1 is connected to the other end of the first capacitor Cs. In the example illustrated in FIGS. 4 and 5, the gate DRg is electrically connected to the first electrode portion E1.

Furthermore, as illustrated in FIG. 2, the power supply voltage node VCCP is connected to the other end of the second capacitor Csub. In the example illustrated in FIGS. 4 and 5, the power supply voltage VCCP is input to the fourth electrode portion E4 via the wiring of the layer L2.

The metal layer ML is disposed in a layer different from the first capacitor Cs and the second capacitor Csub. The metal layer ML is disposed in the layer L2, for example. The metal layer ML is electrically connected to the common electrode portions, that is, the second electrode portion E2 and the third electrode portion E3. Therefore, the metal layer ML is also electrically connected to the source DRs.

Furthermore, the metal layer ML is disposed so as to overlap with at least one electrode portion of at least one capacitor when viewed from the lamination direction. Here, “overlapping” indicates that an outer edge of the metal layer ML is not necessarily located outside an outer edge of the electrode portion in plan view. More specifically, the metal layer ML is disposed so as to cover at least one electrode portion of at least one capacitor when viewed from the lamination direction. Here, “cover” indicates that the outer edge of the metal layer ML is located outside the outer edge of the electrode portion in plan view. In the following description, it is assumed that the metal layer ML covers the first electrode portion E1 in plan view. The metal layer ML is more preferably disposed so as to cover the first electrode portion E1. However, the metal layer ML may not necessarily be disposed so as to cover the first electrode portion E1.

In the example illustrated in FIG. 5, the metal layer ML is disposed so as to cover the first electrode portion E1 electrically connected to the gate DRg when viewed from the lamination direction. Furthermore, the metal layer ML is disposed such that at least a part of the metal layer ML overlaps the third electrode portion E3 when viewed from the lamination direction. This is to connect the metal layer ML and the third electrode portion E3 via the via V (via V2).

The via V is provided so as to extend in the lamination direction. A plurality of the vias V electrically connects the common electrode portions and the metal layer ML. The metal layer ML is disposed so as to electrically connect the respective common electrode portions via the plurality of vias V. More specifically, each of the vias V electrically connects the second electrode portion E2 and the third electrode portion E3 disposed in mutually different layers via the metal layer ML.

Furthermore, the via V includes a via V1 and a via V2.

The via V1 electrically connects the second electrode portion E2 and the metal layer ML. The via V2 electrically connects the third electrode portion E3 and the metal layer ML.

Next, electrostatic capacitances of the first capacitor Cs and the second capacitor Csub will be described.

The capacitance of the first capacitor Cs is usually determined by an area in which the first electrode portion E1 and the second electrode portion E2 overlap each other when viewed from the lamination direction. However, widening the overlapping area is limited by layout arrangement and area restrictions. Here, by utilizing a parasitic capacitance in the circuit, the electrostatic capacitance of the first capacitor Cs can be improved.

As described above, the first electrode portion E1 is larger than the second electrode portion E2, and the metal layer ML is larger than the first electrode portion E1. Therefore, as illustrated in FIG. 5, a part of the metal layer ML faces a part of the first electrode portion E1. That is, the metal layer ML is disposed so as to cover the first electrode portion E1 different from the common electrode portions, the first electrode portion E1 being disposed so as to cover the common electrode portions (second electrode portion E2) as viewed from the lamination direction. As a result, as illustrated in FIG. 4, a parasitic capacitance Cp1 is generated between the metal layer ML and the first electrode portion E1 facing each other. Note that the parasitic capacitance Cp1 is not generated in a region of the second electrode portion E2 in plan view. Furthermore, as described above, the second electrode portion E2, the third electrode portion E3, and the metal layer ML are electrically connected to the source DRs. The first electrode portion E1 covered with the metal layer ML and different from the common electrode portions (second electrode portion E2) is electrically connected to the gate DRg. Therefore, the parasitic capacitance Cp1 is a parasitic capacitance Cgs between the gate and the source of the Drv transistor Q1, and the electrostatic capacitance of the first capacitor Cs can be improved.

Furthermore, the signal line SIG is disposed in the layer L3 above the layers L1 and L2. In a case where the signal line SIG and the first electrode portion E1 overlap each other when viewed from the lamination direction, a parasitic capacitance occurs between the first electrode portion E1 and the signal line SIG. As described above, the first electrode portion E1 is electrically connected to the gate DRg. Therefore, the operation of the Drv transistor Q1 may be adversely affected by the parasitic capacitance, and noise may increase. However, as illustrated in FIGS. 4 and 5, the metal layer ML is disposed so as to cover the first electrode portion E1 that is electrically connected to the gate DRg and is different from the common electrode portions when viewed from the lamination direction. Furthermore, the metal layer ML is disposed in the layer L2 between the layer L1 in which the first electrode portion E1 is disposed and the layer L3 in which the signal line SIG is disposed. Therefore, the metal layer ML is disposed between the first electrode portion E1 and the signal line SIG, and shields the first electrode portion E1. As a result, the influence of the parasitic capacitance in the first electrode portion E1 (gate DRg) can be suppressed, and noise can be suppressed. Note that, although the voltage supply line and the signal line SIG are disposed in the same layer L3, they may be disposed in different layers.

The electrostatic capacitance of the second capacitor Csub is usually determined by an area in which the third electrode portion E3 and the fourth electrode portion E4 overlap each other when viewed from the lamination direction. However, widening the overlapping area is limited by layout arrangement and area restrictions. Here, by utilizing a parasitic capacitance in the circuit, the effective electrostatic capacitance of the second capacitor Csub can be improved.

In the layer L3 above the layers L1 and L2, voltage supply wiring for supplying a predetermined voltage (power supply voltage VCCP) is disposed. When the metal layer ML overlaps the voltage supply wiring as viewed from the lamination direction, a parasitic capacitance Cp2 is generated between the power supply wiring and the metal layer ML as illustrated in FIG. 4. Furthermore, as described above, the third electrode portion E3 and the metal layer ML are electrically connected to the source DRs. The fourth electrode portion E4 different from the common electrode portion in at least one capacitor (second capacitor Csub) is electrically connected to the voltage supply wiring. Therefore, the parasitic capacitance Cp2 can improve the effective electrostatic capacitance of the second capacitor Csub. Furthermore, the overlapping area with the metal layer ML may be increased by increasing the voltage supply wiring or the like. Therefore, the parasitic capacitance Cp2 can be further increased. As a result, the second capacitor Csub can be further increased.

As described above, according to the first embodiment, the first capacitor Cs and the second capacitor Csub are disposed in the same layer. As a result, since the two capacitors can be formed at a time, the number of steps and cost can be reduced.

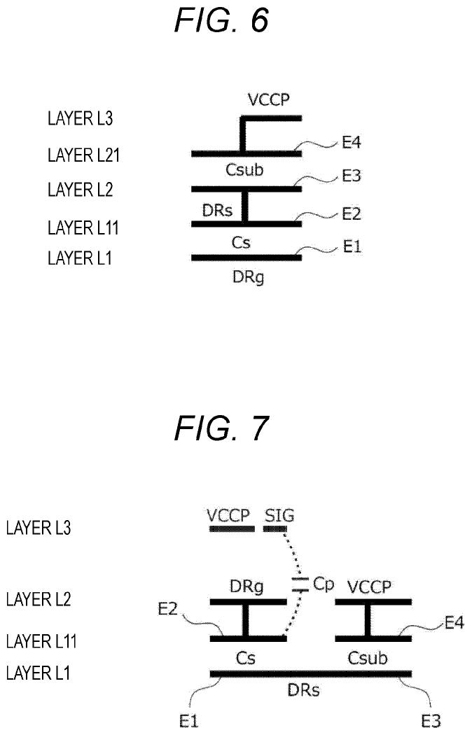

FIG. 6 is a cross-sectional view illustrating an example of a configuration of a first capacitor Cs and a second capacitor Csub according to a first comparative example. The first comparative example is different from the first embodiment in that two capacitors, the first capacitor Cs and the second capacitor Csub, are disposed in different layers.

In the example illustrated in FIG. 6, the third electrode portion E3 is disposed in the layer L2, and the fourth electrode portion E4 is disposed in a layer L21. The layer L21 is a layer between the layer L2 and the layer L3. In this case, since the first capacitor Cs and the second capacitor Csub are separately formed, the number of steps is large and the cost is high.

On the other hand, in the first embodiment, as described above, the first capacitor Cs and the second capacitor Csub can be formed at a time, and the number of steps and the cost can be reduced.

Furthermore, in the first embodiment, the second electrode portion E2 and the third electrode portion E3 that are common electrode portions are disposed in two different layers. As a result, the electrostatic capacitances of the first capacitor Cs and the second capacitor Csub can be increased by the parasitic capacitances in the circuit. By increasing the electrostatic capacitance, it is possible to improve the resistance to luminance variation associated with leakage during light emission, and to improve image quality. Furthermore, by increasing the electrostatic capacitance, correction such as threshold correction can be made more advantageous, and for example, surface roughness and the like can be suppressed to improve image quality. Furthermore, the first electrode portion E1 electrically connected to the gate DRg can be shielded. As a result, the influence of noise due to the parasitic capacitance from the signal line SIG to the gate DRg can be suppressed, and image quality can be improved.

FIG. 7 is a cross-sectional view illustrating an example of a configuration of a first capacitor Cs and a second capacitor Csub according to a second comparative example. The second comparative example is different from the first embodiment in that common electrodes of two capacitors are disposed in the same layer.

In the example illustrated in FIG. 7, the first electrode portion E1 and the third electrode portion E3 are electrically connected. The first electrode portion E1 and the third electrode portion E3 are electrically connected to the source DRs. The second electrode portion E2 is electrically connected to the gate DRg. In this case, there is a possibility that the influence of noise due to a parasitic capacitance from the signal line SIG to the second electrode portion E2 increases.

On the other hand, in the first embodiment, the first electrode portion E1 electrically connected to the gate DRg is disposed in the lower layer L1. Furthermore, the common electrode portion (metal layer ML) is disposed so as to cover the first electrode portion E11 when viewed from the lamination direction. Therefore, the first electrode portion E1 can be shielded, and generation of the parasitic capacitance and noise can be suppressed. As a result, image quality can be improved. Furthermore, the parasitic capacitance in the circuit can improve the effective electrostatic capacitances of the first capacitor Cs and the second capacitor Csub. As a result, the threshold correction and the like can be more appropriately performed, and image quality can be improved.

Note that, in the first embodiment, the two capacitors, the first capacitor Cs and the second capacitor Csub, have been described. However, three or more capacitors may be provided. In this case, the plurality of capacitors is disposed in the same layer. Each of the plurality of capacitors holds a voltage (charge) related to the operation of the OLED 12. Furthermore, a plurality of sets of the first capacitor Cs and the second capacitor Csub may be provided. In this case, the layers disposed between the sets may be different.

Furthermore, in the first embodiment, the first capacitor Cs and the second capacitor Csub are electrically connected to the Drv transistor Q1 for the threshold correction of the Drv transistor Q1. The Drv transistor Q1 is a transistor that drives the OLED 12 on the basis of the signal voltage held in the first capacitor Cs. However, depending on the purpose of providing the capacitor, the present disclosure is not necessarily limited to the Drv transistor Q1. The first capacitor Cs and the second capacitor Csub may be electrically connected to another transistor related to the operation of the OLED 12, such as the WS transistor Q2, the DS transistor Q3, or the AZ transistor Q4, for example.

Furthermore, in the first embodiment, the common electrode portions of the two capacitors, the first capacitor Cs and the second capacitor Csub, are electrically connected to the source of the transistor (Drv transistor Q1). However, as will be described later with reference to a third embodiment, a terminal other than the source of the transistor may be electrically connected to the common electrode portions.

Furthermore, in the first embodiment, the first capacitor Cs and the second capacitor Csub are MIM capacitors. However, as will be described later with reference to the third embodiment and a fourth embodiment, another capacitor may be used.

Furthermore, the embodiment of the present disclosure is not limited to the first embodiment, and can be applied in a case where a plurality of capacitors including common electrodes is provided.

### Modification Example of First Embodiment

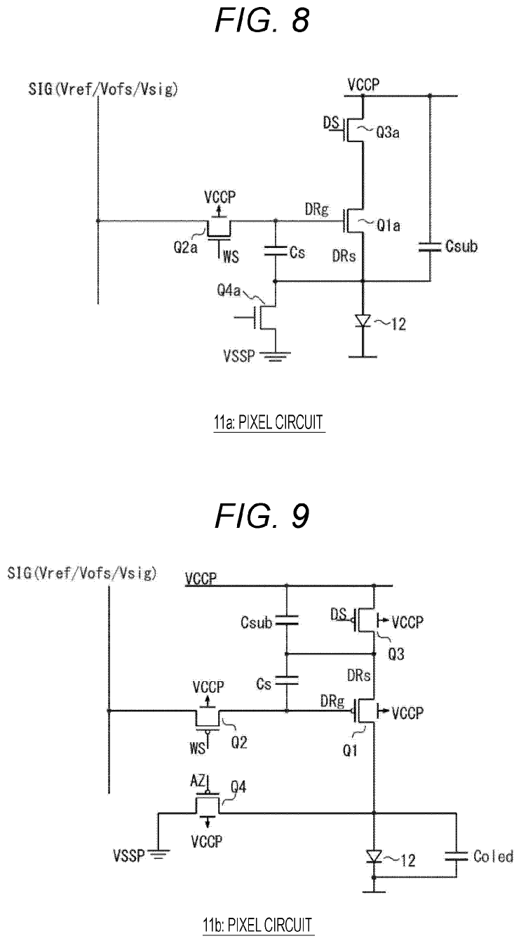

FIG. 8 is a circuit diagram illustrating an example of an internal configuration of a pixel circuit 11a according to a modification example of the first embodiment. The modification example of the first embodiment is different from the first embodiment in a conductivity type of the transistors in the pixel circuit. Hereinafter, differences will be mainly described.

The pixel circuit 11 in FIG. 2 includes the four transistors Q1 to 04 including P-type MOS transistors, but may include N-type MOS transistors. FIG. 8 is a circuit diagram of the pixel circuit 11a according to the modification example in which the transistors Q1 to Q4 in the pixel circuit 11 of FIG. 2 are configured by N-type MOS transistors Qla, Q2a, Q3a, and Q4a. The pixel circuit 11a of FIG. 8 performs the similar operation to the pixel circuit 11 of FIG. 2 although the conductivity type is different.

As in the modification example of the first embodiment, the conductivity types of the transistors may be different. Also in this case, effects equivalent to those of the first embodiment can be obtained.

### Second Embodiment

FIG. 9 is a circuit diagram illustrating an example of an internal configuration of a pixel circuit 11a according to a second embodiment. In the second embodiment, a capacitor Coled is provided as compared with the first embodiment. Hereinafter, differences will be mainly described.

In the pixel circuit 11b of FIG. 9, the capacitor Coled is disposed in parallel with the OLED 12. The capacitor Coled is an auxiliary capacitance. By providing the capacitor Coled, it is possible to compensate for the insufficient capacity of an OLED 12 and to increase a writing gain of the video signal with respect to a first capacitor Cs that is a holding capacity.

As in the second embodiment, the capacitor Coled may be provided. Also in this case, effects equivalent to those of the first embodiment can be obtained.

### Third Embodiment

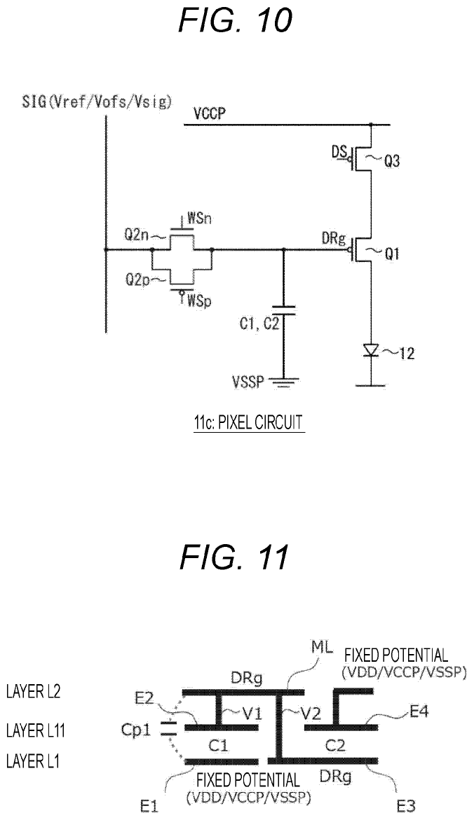

FIG. 10 is a circuit diagram illustrating an example of an internal configuration of a pixel circuit 11c according to a third embodiment. The third embodiment is different from the first embodiment in common electrodes of two capacitors. Hereinafter, differences will be mainly described.

A capacitor C1 and a capacitor C2 are provided instead of the first capacitor Cs and the second capacitor Csub. Note that, although only one capacitor is illustrated in the circuit diagram illustrated in FIG. 10, the two capacitors C1 and C2 connected in parallel are provided.

The capacitor C1 and the capacitor C2 are connected between a gate DRg and a ground voltage node VSSP. The capacitor C1 and the capacitor C2 are connected in parallel to each other. Therefore, the capacitor C1 and the capacitor C2 include common electrodes. Furthermore, the common electrodes of the capacitor C1 and the capacitor C2 are electrically connected to a gate DRg of a Drv transistor Q1.

The capacitor C1 and the capacitor C2 are, for example, a MIM capacitor and a metal-oxide-metal (MOM) capacitor, respectively.

Next, configurations other than the capacitor will be described.

In FIG. 10, as compared with FIG. 2 of the first embodiment, the WS transistor Q2 is made into a CMOS, and the AZ transistor Q4 is not provided. The WS transistor Q2 includes a WS transistor Q2n and a WS transistor Q2p connected in parallel to form a transfer gate. The WS transistor Q2n is an N-type MOS transistor, and a signal WSn is input to a gate thereof. The WS transistor W2p is a P-type MOS transistor, and a signal WSp is input to a gate thereof. For example, an on/off timing is controlled to have a predetermined phase difference between the WS transistor W2n and the WS transistor W2p. As a result, regardless of a signal amplitude level to other pixels in the same row, the influence of the waveform blunting of a write scanning pulse on a mobility correction period can be alleviated, and the display unevenness can be alleviated.

Next, a configuration of the capacitor C1 and the capacitor C2, and a peripheral configuration thereof will be described.

FIG. 11 is a cross-sectional view illustrating an example of a configuration of the capacitor C1 and the capacitor C2 according to the third embodiment. FIG. 12 is a plan view illustrating an example of a configuration of the capacitor C1 and the capacitor C2 according to the third embodiment.

In the example illustrated in FIG. 11, the capacitor C1 includes a first electrode portion E1 and a second electrode portion E2. The capacitor C2 includes a third electrode portion E3 and a fourth electrode portion E4. Similarly to the first embodiment, common electrode portions are the second electrode portion E2 and the third electrode portion E3.

As in the first embodiment, the first electrode portion E1 is larger than the second electrode portion E2, and a metal layer ML is larger than the first electrode portion E1. Therefore, as illustrated in FIG. 12, a part of the metal layer ML faces a part of the first electrode portion E1. As a result, as illustrated in FIG. 11, a parasitic capacitance Cp1 is generated between the metal layer ML and the first electrode portion E1.

Furthermore, the second electrode portion E2, the third electrode portion E3, and the metal layer ML are electrically connected to the gate DRg. The first electrode portion E1 covered with the metal layer ML and different from the common electrode portion (second electrode portion E2) is electrically connected to the voltage supply wiring. In the example illustrated in FIGS. 10 and 11, the first electrode portion E1 is electrically connected to the ground voltage node VSSP, and the potential is fixed. Note that the fourth electrode portion E4 is also electrically connected to the ground voltage node VSSP, and the potential is fixed. Therefore, the parasitic capacitance Cp1 can improve the electrostatic capacitances of the capacitor C1 and the capacitor C2.

As in the third embodiment, the common electrode portions of the two capacitors C1 and C2 may be electrically connected to the gate DRg of the transistor (Drv transistor Q1). Also in this case, effects equivalent to those of the first embodiment can be obtained.

### Fourth Embodiment

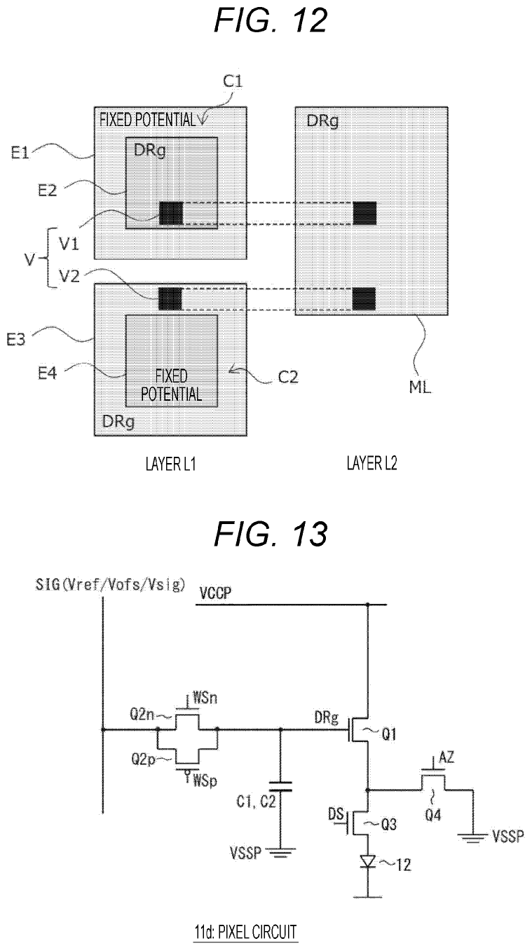

FIG. 13 is a circuit diagram illustrating an example of an internal configuration of a pixel circuit 11d according to a fourth embodiment. The fourth embodiment is different from the third embodiment in a circuit configuration. Hereinafter, differences will be mainly described.

In the example illustrated in FIG. 13, a Drv transistor Q1 and a DS transistor Q3 are N-type MOS transistors. Furthermore, an AZ transistor Q4 which is an N-type MOS transistor is provided.

Furthermore, a capacitor C1 and a capacitor C2 are, for example, an MOM capacitor and a MOS capacitor, respectively.

In the fourth embodiment, as in the third embodiment, common electrode portions of the two capacitors C1 and C2 are electrically connected to a gate DRg of a Drv transistor Q1. Therefore, the fourth embodiment can obtain effects equivalent to those of the third embodiment.

### Fifth Embodiment

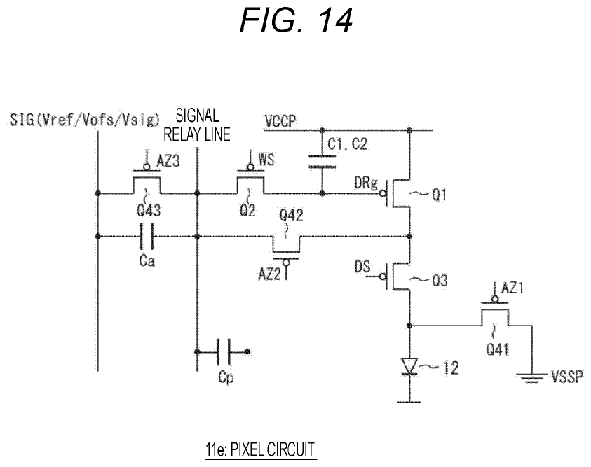

FIG. 14 is a circuit diagram illustrating an example of an internal configuration of a pixel circuit 11e according to a fifth embodiment. The fifth embodiment is different from the third embodiment in a circuit configuration. Hereinafter, differences will be mainly described.

In the example illustrated in FIG. 14, a capacitor C1 and a capacitor C2 are connected between a power supply voltage node VCCP and a gate DRg of a Drv transistor Q1.

Furthermore, the capacitor C1 and the capacitor C2 are, for example, an MIM capacitor and an MOM capacitor, respectively.

Furthermore, a signal relay line relay line is disposed between a signal line SIG and the gate DRg (WS transistor Q2) of the Drv transistor Q1. Furthermore, AZ transistors Q41, Q42, and Q43 and a capacitor Ca are provided. An AZ1 signal, an AZ2 signal, and an AZ3 signal are input to gates of the AZ transistors Q41, Q42, and Q43 that are P-type MOS transistors, respectively.

In the fifth embodiment, as in the third embodiment, common electrode portions of the two capacitors C1 and C2 are electrically connected to the gate DRg of the Drv transistor Q1. Therefore, the fifth embodiment can obtain effects equivalent to those of the third embodiment.

### Sixth Embodiment

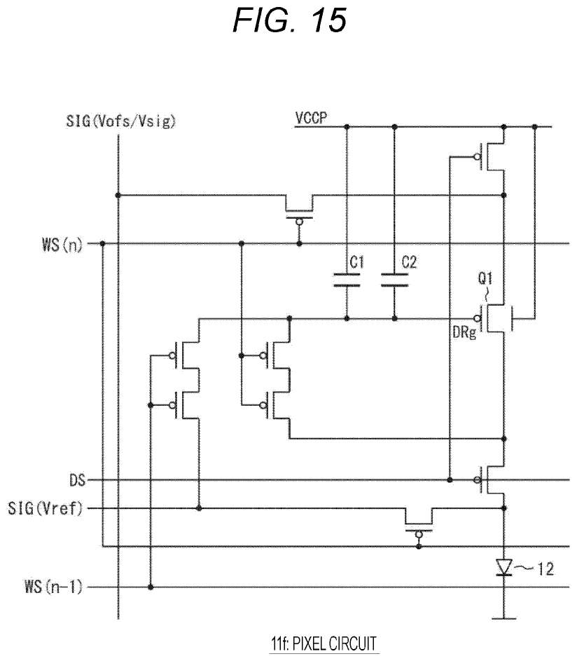

FIG. 15 is a circuit diagram illustrating an example of an internal configuration of a pixel circuit 11f according to a sixth embodiment. The sixth embodiment is different from the third embodiment in a circuit configuration.

In the example illustrated in FIG. 15, similarly to FIG. 14, a capacitor C1 and a capacitor C2 are connected between a power supply voltage node VCCP and a gate DRg of a Drv transistor Q1.

In the sixth embodiment, as in the third embodiment, common electrode portions of the two capacitors C1 and C2 are electrically connected to the gate DRg of the Drv transistor Q1. Therefore, the sixth embodiment can obtain effects equivalent to those of the third embodiment.

### (Application Example of Display Device 1 and Electronic Device 50 According to Present Disclosure)

### First Application Example

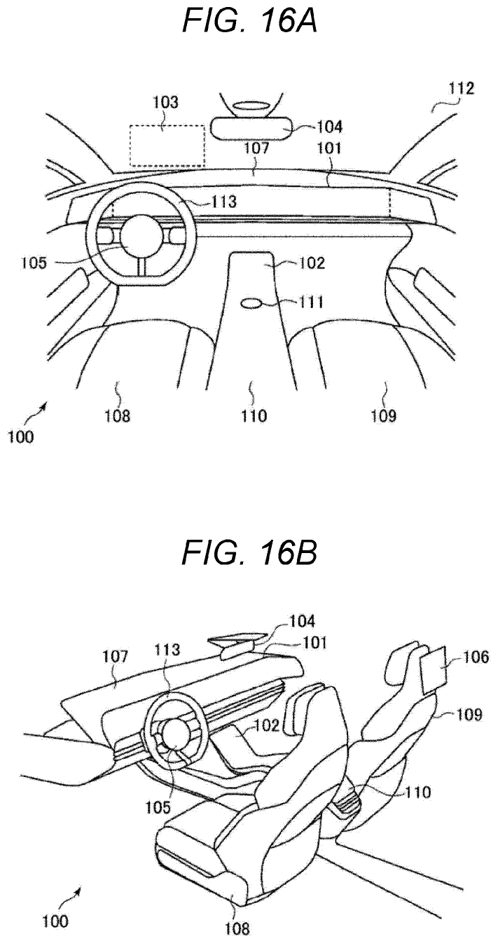

The display device 1 according to the present disclosure can be mounted on various electronic devices. FIGS. 16A and 16B are diagrams illustrating an internal configuration of a vehicle 100 that is a first application example of an electronic device 50 including the display device 1 according to the present disclosure. FIG. 16A is a diagram illustrating an internal state of the vehicle 100 from a rear side to a front side of the vehicle 100, and FIG. 16B is a diagram illustrating an internal state of the vehicle 100 from an oblique rear side to an oblique front side of the vehicle 100.

The vehicle 100 of FIGS. 16A and 16B includes a center display 101, a console display 102, a head-up display 103, a digital rear mirror 104, a steering wheel display 105, and a rear entertainment display 106.

The center display 101 is disposed on a dashboard 107 at a position facing a driver seat 108 and a passenger seat 109. FIG. 16 illustrates an example of the center display 101 having a horizontally long shape extending from a side of the driver seat 108 to a side of the passenger seat 109, but the screen size and arrangement location of the center display 101 are arbitrary. The center display 101 can display information detected by various sensors. As a specific example, the center display 101 can display a captured image captured by an image sensor, a distance image to an obstacle in front of or on a side of the vehicle measured by a ToF sensor, a passenger's body temperature detected by an infrared sensor, and the like. The center display 101 can be used to display, for example, at least one of safety-related information, operation-related information, a life log, health-related information, authentication/identification-related information, or entertainment-related information.

The safety-related information is information such as doze detection, looking-away detection, mischief detection of a child riding together, presence or absence of wearing of a seat belt, and detection of leaving of an occupant, and is, for example, information detected by a sensor superimposed on a back side of the center display 101. The operation-related information detects a gesture related to the operation of the occupant using the sensor. The sensed gestures may include an operation of various types of equipment in the vehicle 100. For example, operations of air conditioning equipment, a navigation device, an AV device, a lighting device, and the like are sensed. The life log includes a life log of all the occupants. For example, the life log includes an action record of each occupant in the conveyance. By acquiring and storing the life log, it is possible to check a state of the occupant at a time of an accident. The health-related information detects a body temperature of the occupant using a temperature sensor, and estimates the health state of the occupant on the basis of the detected body temperature. Alternatively, the face of the occupant may be imaged by using an image sensor, and the health condition of the occupant may be estimated from the imaged facial expression. Moreover, a conversation may be made with the occupant in automatic voice, and the health condition of the occupant may be estimated on the basis of an answer content of the occupant. The authentication/identification-related information includes a keyless entry function of performing face authentication using a sensor, an automatic adjustment function of a sheet height and position in face identification, and the like. The entertainment-related information includes a function of detecting operation information of the AV device by the occupant using the sensor, a function of recognizing the face of the occupant by the sensor and providing content suitable for the occupant by the AV device, and the like.

The console display 102 can be used to display the life log information, for example. The console display 102 is arranged near a shift lever 111 of a center console 110 between the driver seat 108 and the passenger seat 109. The console display 102 can also display information detected by various sensors. Furthermore, the console display 102 may display an image of a periphery of the vehicle captured by the image sensor, or may display an image of a distance to an obstacle in the periphery of the vehicle.

The head-up display 103 is virtually displayed behind a windshield 112 in front of the driver seat 108. The head-up display 103 can be used to display, for example, at least one of safety-related information, operation-related information, a life log, health-related information, authentication/identification-related information, or entertainment-related information. Since the head-up display 103 is virtually arranged in front of the driver seat 108 in many cases, the head-up display 103 is suitable for displaying information directly related to an operation of the vehicle 100 such as a speed of the vehicle 100 and a remaining amount of fuel (a battery).

The digital rear mirror 104 can not only display the rear of the vehicle 100 but also display the state of the occupant in the rear seat, and thus can be used to display the life log information, for example, by disposing the sensor to be superimposed on a back surface side of the digital rear mirror 104.

The steering wheel display 105 is arranged near a center of a steering wheel 113 of the vehicle 100. The steering wheel display 105 can be used to display, for example, at least one of safety-related information, operation-related information, a life log, health-related information, authentication/identification-related information, or entertainment-related information. In particular, since the steering wheel display 105 is close to the driver's hand, the steering wheel display 105 is suitable for displaying the life log information such as a body temperature of the driver, or for displaying information regarding an operation of the AV device, air conditioning equipment, or the like.

The rear entertainment display 106 is attached to a back side of the driver seat 108 and the passenger seat 109, and is for viewing by an occupant in the rear seat. The rear entertainment display 106 can be used to display, for example, at least one of safety-related information, operation-related information, a life log, health-related information, authentication/identification-related information, or entertainment-related information. In particular, since the rear entertainment display 106 is in front of the occupant in the rear seat, information related to the occupant in the rear seat is displayed. For example, information regarding the operation of the AV device or the air conditioning facility may be displayed, or a result of measuring the body temperature or the like of the occupant in the back seat by the temperature sensor may be displayed.

The display device 1 according to the present disclosure can be applied to the center display 101, the console display 102, the head-up display 103, the digital rear mirror 104, the steering wheel display 105, and the rear entertainment display 106.

### Second Application Example

The display device 1 according to the present disclosure is applicable not only to various displays used in vehicles but also to displays mounted on various electronic devices 50.

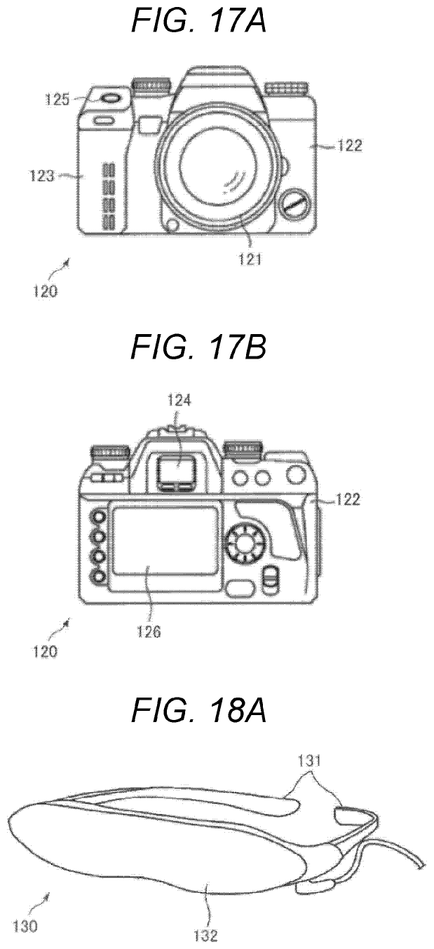

FIG. 17A is a front view of a digital camera 120 as a second application example of the electronic device 50, and FIG. 17B is a rear view of the digital camera 120. The digital camera 120 in FIGS. 17A and 17B illustrates an example of a single-lens reflex camera in which a lens 121 is replaceable, but is also applicable to a camera in which the lens 121 is not replaceable.

In the camera of FIGS. 17A and 17B, when a person who captures an image looks into an electronic viewfinder 124 to determine a composition while holding a grip 123 of a camera body 122, and presses a shutter 125 while adjusting the focus, the image-capturing data is stored in a memory in the camera. As illustrated in FIG. 17B, a monitor screen 126 that displays captured data and the like, a live image, and the like, and the electronic viewfinder 124 are provided on a back side of the camera. Furthermore, a sub screen that displays setting information such as a shutter speed and an exposure value may be provided on an upper surface of the camera.

By applying the display device 1 according to the present disclosure to the monitor screen 126, the electronic viewfinder 124, the sub screen, and the like used for the camera, it is possible to reduce the cost and improve the display quality.

### Third Application Example

The display device 1 according to the present disclosure is also applicable to a head mounted display (Hereinafter, referred to as an HMD.). The HMD can be used for virtual reality (VR), augmented reality (AR), mixed reality (MR), substitutional reality (SR), and the like.

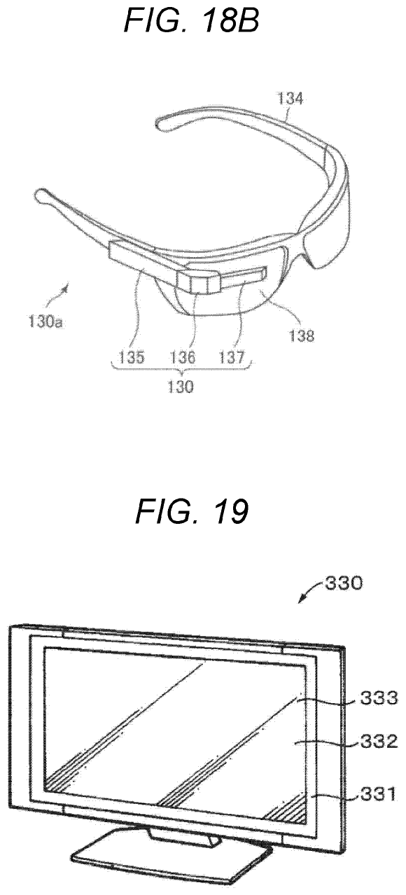

FIG. 18A is an external view of an HMD 130 that is a third application example of the electronic device 50. The HMD 130 of FIG. 18A includes a mounting member 131 for wearing over human eyes. The mounting member 131 is hooked and fixed to a human ear, for example. A display device 132 is provided inside the HMD 130, and a wearer of the HMD 130 can visually recognize a stereoscopic image and the like with the display device 132. The HMD 130 includes, for example, a wireless communication function, an acceleration sensor, and the like, and can switch a stereoscopic image and the like displayed on the display device 132 in accordance with a posture, a gesture, and the like of the wearer. The display device 1 illustrated in FIG. 1 can be applied to the display device 132 in FIG. 18A.

Furthermore, a camera may be provided in the HMD 130 to capture an image around the wearer, and an image obtained by combining the captured image of the camera and an image generated by a computer may be displayed on the display device 132. For example, arranging a camera to overlap with a back surface side of the display device 132 visually recognized by the wearer of the HMD 130, capturing an image of a periphery of an eye of the wearer with the camera, and displaying the captured image on another display provided on an outer surface of the HMD 130, a person around the wearer can grasp expression of the face and a movement of the eyes of the wearer in real time.

Note that various types of the HMD 130 are conceivable. For example, as illustrated in FIG. 18B, the display device 1 according to the present disclosure can also be applied to a smart glass 130a that displays various types of information on glasses 134. The smart glass 130a in FIG. 18B includes a main body portion 135, an arm portion 136, and a lens barrel portion 137. The main body portion 135 is connected to the arm portion 136. The main body portion 135 is detachable from the glasses 134. The main body portion 135 incorporates a display unit and a control board for control of an operation of the smart glass 130a. The main body portion 135 and the lens barrel are connected to each other via the arm portion 136. The lens barrel portion 137 emits image light emitted from the main body portion 135 through the arm portion 136, to a lens 138 side of the glasses 134. This image light enters human eyes through the lens 138. The wearer of the smart glass 130a in FIG. 18B can visually recognize not only the surrounding situation but also various types of information emitted from the lens barrel portion 137, similarly to normal glasses.

### Fourth Application Example

The display device 1 according to the present disclosure is also applicable to a television device (Hereinafter, TV).

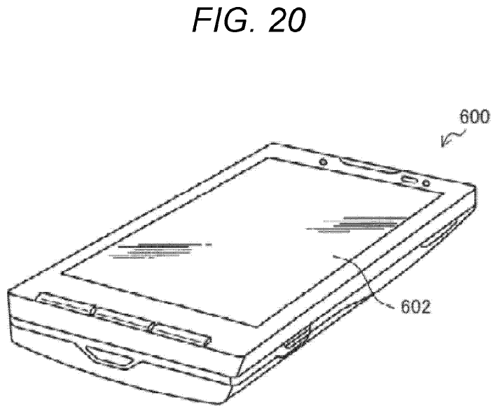

FIG. 19 is an external view of a TV 330 that is a fourth application example of the electronic device 50. The TV 330 includes, for example, a video display screen unit 331 including a front panel 332 and a filter glass 333. The display device 1 according to the present disclosure is applicable to the video display screen unit 331.

As described above, according to the display device 1 of the present disclosure, the TV 330 with low cost and excellent display quality can be realized.

### Fifth Application Example

The display device 1 according to the present disclosure is also applicable to a smartphone and a mobile phone. FIG. 20 is an external view of a smartphone 600 that is a fifth application example of the electronic device 50. The smartphone 600 includes a display unit 602 that displays various types of information, an operation unit including a button or the like that receives a scan input by the user, and the like. The display device 1 according to the present disclosure can be applied to the display unit 602.

Note that the present technology can have the following configurations.

(1) A display device including:
a light emitting element;
a first capacitor including a first electrode and a second electrode;
a second capacitor including a third electrode and a fourth electrode; and
a drive transistor that supplies, to the light emitting element, a current corresponding to a voltage accumulated in the first capacitor and a voltage accumulated in the second capacitor,
in which
the second electrode is electrically connected to the third electrode, and
the second electrode and the third electrode are disposed in different layers.

(2) The display device according to (1), further including a metal layer that is disposed in a layer different from the first capacitor and the second capacitor so as to overlap with the first electrode and the second electrode when viewed from a lamination direction, and is electrically connected to the second electrode and the third electrode.

(3) The display device according to (2), in which the metal layer is disposed so as to cover the first electrode and the second electrode when viewed from the lamination direction.

(4) The display device according to (2) or (3), in which the metal layer is disposed so as to overlap with the first electrode disposed so as to cover the second electrode when viewed from the lamination direction.

(5) The display device according to (4), in which
the first electrode is electrically connected to a gate of the drive transistor, and
the second electrode, the third electrode, and the metal layer are electrically connected to a source of the drive transistor.

(6) The display device according to (4), in which
the first electrode is electrically connected to a voltage supply wiring that supplies a predetermined voltage, and
the second electrode, the third electrode, and the metal layer are electrically connected to a gate of the drive transistor.

(7) The display device according to any one of (2) to (6), in which the metal layer is disposed so as to overlap with a voltage supply wiring that supplies a predetermined voltage when viewed from the lamination direction.

(8) The display device according to (7), in which the fourth electrode is electrically connected to the voltage supply wiring.

(9) The display device according to any one of (2) to (8), in which the metal layer is disposed so as to overlap with the first electrode electrically connected to a gate of the drive transistor when viewed from the lamination direction.

(10) The display device according to (9), in which
the first electrode electrically connected to the gate is disposed so as to overlap with a signal line when viewed from the lamination direction, and
the metal layer is disposed in a layer between a layer in which the first electrode is disposed and a layer in which the signal line is disposed.

(11) The display device according to any one of (2) to (10), further including a plurality of columnar electrode portions provided so as to extend in the lamination direction and electrically connecting each of the second electrode and the third electrode to the metal layer,
in which the metal layer is disposed so as to electrically connect the second electrode and the third electrode via a plurality of the columnar electrode portions.

(12) The display device according to (1) to (11), in which
the first capacitor accumulates a first voltage related to an operation of the drive transistor, and
the second capacitor accumulates a second voltage different from the first voltage.

(13) The display device according to any one of (1) to (12), in which each of the first capacitor and the second capacitor includes a metal-insulator-metal (MIM) capacitor, a metal-oxide-metal (MOM) capacitor, or a metal-oxide-semiconductor (MOS) capacitor.

(14) An electronic device including:
a light emitting element;
a first capacitor including a first electrode and a second electrode;
a second capacitor including a third electrode and a fourth electrode; and
a drive transistor that supplies, to the light emitting element, a current corresponding to a voltage accumulated in the first capacitor and a voltage accumulated in the second capacitor,
in which
the second electrode is electrically connected to the third electrode, and
the second electrode and the third electrode are disposed in different layers.

Aspects of the present disclosure are not limited to the above-described individual embodiments, but include various modifications that can be conceived by those skilled in the art, and the effects of the present disclosure are not limited to the above-described contents. That is, various additions, modifications, and partial deletions are possible without departing from the conceptual idea and spirit of the present disclosure derived from the matters defined in the claims and equivalents thereof.

### REFERENCE SIGNS LIST

1 Display device
12 OLED
50 Electronic device
Cs First capacitor
Csub Second capacitor
C1 Capacitor
C2 Capacitor
VCCP Power supply voltage node
Q1 Drv transistor
Q2 WS transistor
Q3 DS transistor
Q4 AZ transistor

1. A display device comprising:
a light emitting element;
a first capacitor including a first electrode and a second electrode;
a second capacitor including a third electrode and a fourth electrode; and
a drive transistor that supplies, to the light emitting element, a current corresponding to a voltage accumulated in the first capacitor and a voltage accumulated in the second capacitor,
wherein
the second electrode is electrically connected to the third electrode, and
the second electrode and the third electrode are disposed in different layers.

2. The display device according to claim 1, further comprising a metal layer that is disposed in a layer different from the first capacitor and the second capacitor so as to overlap with the first electrode and the second electrode when viewed from a lamination direction, and is electrically connected to the second electrode and the third electrode.

3. The display device according to claim 2, wherein the metal layer is disposed so as to cover the first electrode and the second electrode when viewed from the lamination direction.

4. The display device according to claim 2, wherein the metal layer is disposed so as to overlap with the first electrode disposed so as to cover the second electrode when viewed from the lamination direction.

5. The display device according to claim 4, wherein
the first electrode is electrically connected to a gate of the drive transistor, and
the second electrode, the third electrode, and the metal layer are electrically connected to a source of the drive transistor.

6. The display device according to claim 4, wherein
the first electrode is electrically connected to a voltage supply wiring that supplies a predetermined voltage, and
the second electrode, the third electrode, and the metal layer are electrically connected to a gate of the drive transistor.

7. The display device according to claim 2, wherein the metal layer is disposed so as to overlap with a voltage supply wiring that supplies a predetermined voltage when viewed from the lamination direction.

8. The display device according to claim 7, wherein the fourth electrode is electrically connected to the voltage supply wiring.

9. The display device according to claim 2, wherein the metal layer is disposed so as to overlap with the first electrode electrically connected to a gate of the drive transistor when viewed from the lamination direction.

10. The display device according to claim 9, wherein
the first electrode electrically connected to the gate is disposed so as to overlap with a signal line when viewed from the lamination direction, and
the metal layer is disposed in a layer between a layer in which the first electrode is disposed and a layer in which the signal line is disposed.

11. The display device according to claim 2, further comprising a plurality of columnar electrode portions provided so as to extend in the lamination direction and electrically connecting each of the second electrode and the third electrode to the metal layer,
wherein the metal layer is disposed so as to electrically connect the second electrode and the third electrode via a plurality of the columnar electrode portions.

12. The display device according to claim 1, wherein
the first capacitor accumulates a first voltage related to an operation of the drive transistor, and
the second capacitor accumulates a second voltage different from the first voltage.

13. The display device according to claim 1, wherein each of the first capacitor and the second capacitor includes a metal-insulator-metal (MIM) capacitor, a metal-oxide-metal (MOM) capacitor, or a metal-oxide-semiconductor (MOS) capacitor.

14. An electronic device comprising:
a light emitting element;
a first capacitor including a first electrode and a second electrode;
a second capacitor including a third electrode and a fourth electrode; and
a drive transistor that supplies, to the light emitting element, a current corresponding to a voltage accumulated in the first capacitor and a voltage accumulated in the second capacitor,
wherein
the second electrode is electrically connected to the third electrode, and
the second electrode and the third electrode are disposed in different layers.
